(19) United States
(12) Patent Application Publication
(10) Pub. No.: US 2020/0194524 A1
(43) Pub. Date: Jun. 18, 2020

(54) ORGANIC LIGHT EMITTING DIODE DISPLAY AND METHOD OF MANUFACTURING THEREOF

(71) Applicant: Wuhan China Star Optoelectronics Semiconductor Display Technology Co., Ltd., Wuhan (CN)

(72) Inventors: Wu DING, (US); Songshan Li, Wuhan (CN)

(73) Assignee: Wuhan China Star Optoelectronics Semiconductor Display Technology Co., Ltd., Wuhan (CN)

(21) Appl. No.: 16/333,232

(22) PCT Filed: Jan. 4, 2019
(86) PCT No.: PCT/CN2019/070380

§ 371 Date: Mar. 14, 2019

(30) Foreign Application Priority Data
Dec. 13, 2018 (CN) 201811522887.5

(51) Int. Cl. H01L 27/32

(52) U.S. Cl. CPC H01L 27/3248; H01L 2227/323; H01L 27/3262; H01L 27/3246

(57) ABSTRACT

An organic light emitting diode (OLED) display and a method of manufacturing thereof are provided. The OLED display panel includes a substrate; a thin film transistor (TFT) layer on the substrate; a pixel defining layer above the TFT layer, the pixel defining layer having a via hole; a light emitting unit located in the via hole of the pixel defining layer, the light emitting unit includes an anode located at a bottom of the via hole, an organic light emitting material above the anode, a cathode located above the organic light emitting material, and a first reflective metal layer between the organic light emitting material and the pixel defining layer.

### BACKGROUND OF INVENTION

### Field of Invention

The present invention relates to the field of display technologies, and in particular, to an organic light emitting diode (OLED) display and a method of manufacturing thereof.

### Description of Prior Art

In a top emitting organic light emitting diode (OLED) display, each of the light emitting units includes an anode above a thin film transistor layer, an organic light emitting material above the anode, and a cathode over the light emitting material. Each adjacent light emitting unit is isolated from each other by an insulating layer, which is referred to as a pixel defining layer. The pixel defining layer is formed by depositing the insulating layer over the thin film transistor, and patterning the insulating layer by photolithography to form a plurality of through holes for manufacturing the light emitting units. In this way, each of the light emitting units is surrounded by an insulating material to achieve electrical insulation from adjacent light emitting units.

In prior art, a material forming the pixel defining layer is usually silicon oxide or silicon nitride, and the transmittance of the two materials to visible light is about 70%. When OLED emits light upward, a part of the light is obliquely passed through the pixel defining layer, which reduces luminous efficiency of an OLED device and seriously affects the luminescent properties of the OLED.

### SUMMARY OF INVENTION

The present invention provides an organic light emitting diode (OLED) display and a manufacturing method thereof, which solve the technical problem that light is absorbed by the pixel defining layer and affects the luminous efficiency of the OLED display.

In a first aspect, the present invention provides an OLED display panel comprising:

a substrate;

a thin film transistor (TFT) layer on the substrate;

a pixel defining layer above the TFT layer, the pixel defining layer having a via hole;

a light emitting unit located in the via hole of the pixel defining layer, the light emitting unit comprises an anode located at a bottom of the via hole, an organic light emitting material above the anode, a cathode located above the organic light emitting material, and a first reflective metal layer between the organic light emitting material and the pixel defining layer;

wherein the via hole of the pixel defining layer has a rectangular cross section in a direction parallel to the substrate, and an inverted trapezoid cross section perpendicular to the direction of the substrate; wherein, the inverted trapezoid is an isosceles trapezoid, and an angle between the waist of the inverted trapezoid and the vertical direction is greater than or equal to 5°.

Wherein, the anode of the light emitting unit is a laminated structure of a first transparent conductive layer/a second reflective metal layer/a second transparent conductive layer.

Wherein, a material of the first reflective metal layer and the second reflective metal layer is silver.

In a second aspect, the present invention provides an organic light emitting diode (OLED) display panel comprising:

a substrate;

a thin film transistor (TFT) layer on the substrate;

a pixel defining layer above the TFT layer, the pixel defining layer having a via hole;

a light emitting unit located in the via hole of the pixel defining layer, the light emitting unit comprises an anode located at a bottom of the via hole, an organic light emitting material above the anode, a cathode located above the organic light emitting material, and a first reflective metal layer between the organic light emitting material and the pixel defining layer.

Wherein, the anode of the light emitting unit is a laminated structure of a first transparent conductive layer/a second reflective metal layer/a second transparent conductive layer.

Wherein, a material of the first reflective metal layer and the second reflective metal layer is silver.

Wherein, the via hole of the pixel defining layer has a rectangular cross section in a direction parallel to the substrate, and an inverted trapezoid cross section perpendicular to the direction of the substrate; wherein, the inverted trapezoid is an isosceles trapezoid, and an angle between the waist of the inverted trapezoid and the vertical direction is greater than or equal to 5°.

In a third aspect, the present invention provides a method of manufacturing an organic light emitting diode (OLED) display panel comprising the steps of:

providing a substrate;

forming a thin film transistor (TFT) layer on the substrate;

forming a patterned pixel defining layer over the TFT layer, the pixel defining layer having a via hole;

forming a light emitting unit in the via hole of the pixel defining layer; wherein

the light emitting unit comprises an anode located at a bottom of the via hole, an organic light emitting material above the anode, a cathode located above the organic light emitting material, and a first reflective metal layer between the organic light emitting material and the pixel defining layer.

Wherein, a method of forming a patterned pixel definition layer over the TFT layer comprises the steps of:

depositing an insulating material layer over the thin film transistor;

coating a photoresist over the insulating material layer;

developing the photoresist with a set mask to remove the photoresist over a region where the via hole is to be formed;

removing the insulating material layer not covered by the photoresist by etching, forming a via hole penetrating the insulating material layer, exposing the thin film transistor layer underlying the insulating material layer.

Wherein, a method of etching the insulating material layer is dry etching, comprising ion milling etching, plasma etching, and reactive ion etching.

Wherein, a method of forming a light emitting unit in the via hole of the pixel defining layer comprises the steps of:

evaporating the anode at the bottom of the via hole;

forming the first reflective metal layer on a sidewall of the via hole defined by the pixel defining layer, the first reflective metal layer is disposed above the anode;

forming an organic light emitting material above the anode, a sidewall of the organic light emitting material is disposed adjacent to the first reflective metal layer;

forming a cathode over the organic light emitting material.

Wherein, a method of evaporating the anode at the bottom of the via hole comprises the steps of:

forming a photoresist covering a top and a sidewall of the pixel defining layer;

forming a stacked structure covering the photoresist and the via hole, the stacked structure comprises a first transparent conductive layer at a bottom of the pixel defining layer, a second reflective metal layer disposed above the first transparent conductive layer, and a second transparent conductive layer above the second reflective metal layer;

removing the photoresist, and so that the stacked structure over the photoresist is removed to form the anode at the bottom of the via hole.

Wherein, a method of forming a first reflective metal layer on a sidewall of the via hole of the pixel defining layer comprises the steps of:

forming a metal layer covering the anode, the top and sidewall of the pixel defining layer;

forming a photoresist covering the metal layer, and patterning the photoresist to cover only a metal layer located on a sidewall of the pixel defining layer;

removing a metal layer not covered by the photoresist by photolithography, and then removing the photoresist.

The present invention forms a layer of reflective metal on the sidewall adjacent to the luminescent material of the pixel defining layer, so that the light emitted by the light emitting units is reflected to the display screen by the pixel defining layer instead of being absorbed by the pixel defining layer. Thereby, the reflectivity of the light is enhanced, the luminous efficiency of the OLED device is greatly improved, and the luminescent characteristics of the OLED device are improved.

### BRIEF DESCRIPTION OF DRAWINGS

FIG. 1 to FIG. 5 are structural diagrams of an organic light emitting diode (OLED) display screen in each step of a method for manufacturing an OLED display according to an embodiment of the present invention;

FIG. 6 is a structural diagram of an OLED display according to an embodiment of the present invention.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

The present invention provides an organic light emitting diode (OLED) display and a manufacturing method thereof, which solve the technical problem that light is absorbed by the pixel defining layer and affects the luminous efficiency of the OLED display. The present invention will now be described in detail with reference to the drawings.

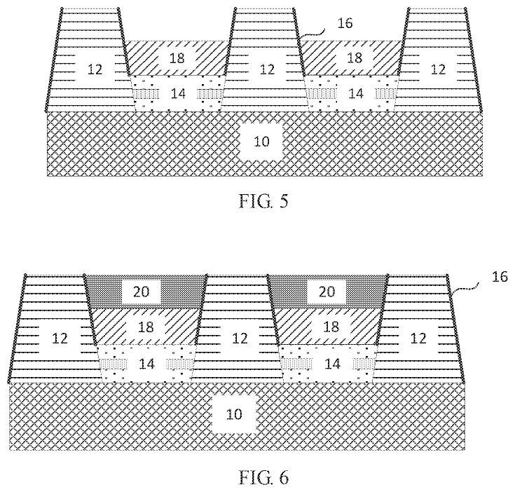

Referring to FIG. 6, FIG. 6 is a structural diagram of an OLED display according to an embodiment of the present invention.

the present invention provides an OLED display panel comprising a substrate 10; a thin film transistor (TFT) layer (not shown in the figure) on the substrate; a pixel defining layer 12 above the TFT layer, the pixel defining layer having a via hole; a light emitting unit located in the via hole of the pixel defining layer, the light emitting unit comprises an anode 14 located at a bottom of the via hole, an organic light emitting material 18 above the anode, a cathode 20 located above the organic light emitting material, and a first reflective metal layer 16 between the organic light emitting material 18 and the pixel defining layer 12.

In the present embodiment, the anode 14 of the light emitting unit is a laminated structure of a first transparent conductive layer 142/a second reflective metal layer 144/a second transparent conductive layer 146. The second reflective metal layer 144 can reflect the light emitted by the light emitting unit toward the substrate 10 to the upper side of the OLED display screen, thereby further enhancing luminous efficiency.

Preferably, because silver has excellent electrical conductivity and light reflectivity, in the present embodiment, the material of the first reflective metal layer 16 and the second reflective metal layer 144 are silver.

In the present embodiment, the via hole of the pixel defining layer 12 has a rectangular cross section in a direction parallel to the substrate 10, and an inverted trapezoid cross section perpendicular to the direction of the substrate 10; wherein, the inverted trapezoid is an isosceles trapezoid, and an angle between the waist of the inverted trapezoid and the vertical direction is greater than or equal to 5°. The inverted trapezoidal design increases the area of an open area where the light emitting unit is disposed, and can further increase the light emitting efficiency of the OLED display; at the same time, an inclined surface is more favorable for the formation of a first metal light reflecting layer than a vertical surface.

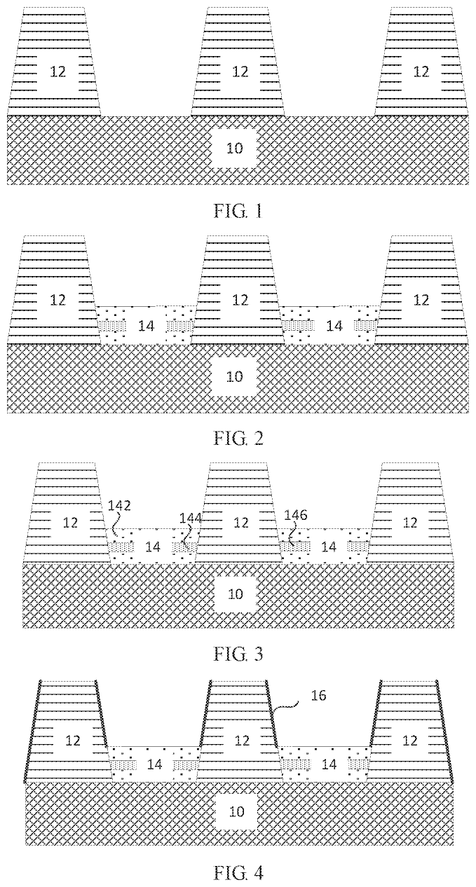

Correspondingly, referring to FIG. 1 to FIG. 5, FIG. 1 to FIG. 5 are structural diagrams of an OLED display screen in each step of a method for manufacturing an OLED display according to an embodiment of the present invention. The present invention provides the method of manufacturing an OLED display panel comprising the steps of:

providing a substrate 10;

forming a TFT layer on the substrate 10;

forming a patterned pixel defining layer 12 over the TFT layer, the pixel defining layer 12 having a via hole;

forming a light emitting unit in the via hole of the pixel defining layer; wherein

the light emitting unit comprises an anode 14 located at a bottom of the via hole, an organic light emitting material 18 above the anode, a cathode 20 located above the organic light emitting material, and a first reflective metal layer 16 between the organic light emitting material 18 and the pixel defining layer 12.

In the present embodiment, first, referring to FIG. 1, a substrate 10 is provided, and a thin film transistor layer (not shown) is formed on the substrate 10.

Thereafter, as shown in FIG. 2, a patterned pixel defining layer 12 is formed over the thin film transistor layer, the pixel defining layer 12 having a via hole.

In the present embodiment, a method of forming a patterned pixel definition layer 12 over the TFT layer comprises the steps of: depositing an insulating material layer over the thin film transistor; coating a photoresist over the insulating material layer; developing the photoresist with a set mask to remove the photoresist over a region where the via hole is to be formed; removing the insulating material layer not covered by the photoresist by etching, forming a via hole penetrating the insulating material layer, exposing the thin film transistor layer underlying the insulating material layer. In the present embodiment, a method of etching the insulating material layer is dry etching, comprising ion milling etching, plasma etching, and reactive ion etching.

In the present embodiment, the via hole of the pixel defining layer 12 has a rectangular cross section in a direction parallel to the substrate 10, and an inverted trapezoid cross section perpendicular to the direction of the substrate 10; wherein, the inverted trapezoid is an isosceles trapezoid, and an angle between the waist of the inverted trapezoid and the vertical direction is greater than or equal to 5°. The inverted trapezoidal design increases the area of an open area where the light emitting unit is disposed, and can further increase the light emitting efficiency of the OLED display; at the same time, an inclined surface is more favorable for the formation of a first metal light reflecting layer than a vertical surface.

Thereafter, forming the light emitting unit in the via hole of the pixel defining layer, the light emitting unit comprises an anode 14 located at a bottom of the via hole, an organic light emitting material 18 above the anode, a cathode 20 located above the organic light emitting material, and a first reflective metal layer 16 between the organic light emitting material 18 and the pixel defining layer 12.

In the present embodiment, a method of forming the light emitting unit in the via hole of the pixel defining layer 12 comprises the steps of evaporating the anode 14 at the bottom of the via hole; forming the first reflective metal layer 16 on a sidewall of the via hole defined by the pixel defining layer 12, the first reflective metal layer 16 is disposed above the anode 14; forming an organic light emitting material 18 above the anode, a sidewall of the organic light emitting material 18 is disposed adjacent to the first reflective metal layer 16; the cathode 20 is formed over the organic light emitting material 18.

As shown in FIG. 3, in the present embodiment, a method of evaporating the anode 14 at the bottom of the via hole comprises the steps of forming the photoresist covering a top and a sidewall of the pixel defining layer 12; forming a stacked structure covering the photoresist and the via hole, the stacked structure comprises a first transparent conductive layer 142 at a bottom of the pixel defining layer 12, a second reflective metal layer 144 disposed above the first transparent conductive layer 142, and a second transparent conductive layer 146 above the second reflective metal layer 144; removing the photoresist, and so that the stacked structure over the photoresist is removed to form the anode 14 at the bottom of the via hole.

In the present embodiment, as shown in FIG. 4 and FIG. 5, forming the first reflective metal layer 16 on the sidewall of the via hole of the pixel defining layer 12. The method comprises the steps of forming a metal layer covering the anode 14, the top and sidewall of the pixel defining layer 12, as shown in FIG. 5; forming the photoresist covering the metal layer, and patterning the photoresist to cover only a metal layer located on a sidewall of the pixel defining layer 12; removing a metal layer not covered by the photoresist by photolithography, and then removing the photoresist, as shown in FIG. 5.

Thereafter, forming the organic light emitting material 18 over the anode 14 and the cathode 20 over the organic light emitting material 18 to form an OLED device, as shown in FIG. 6.

The present invention forms a layer of reflective metal on the sidewall adjacent to the luminescent material of the pixel defining layer, so that the light emitted by the light emitting units is reflected to the display screen by the pixel defining layer instead of being absorbed by the pixel defining layer. Thereby, the reflectivity of the light is enhanced, the luminous efficiency of the OLED device is greatly improved, and the luminescent characteristics of the OLED device are improved.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. An organic light emitting diode (OLED) display panel, comprising:
a substrate;
a thin film transistor (TFT) layer on the substrate;
a pixel defining layer above the TFT layer, the pixel defining layer having a via hole;
a light emitting unit located in the via hole of the pixel defining layer, the light emitting unit comprises an anode located at a bottom of the via hole, an organic light emitting material above the anode, a cathode located above the organic light emitting material, and a first reflective metal layer between the organic light emitting material and the pixel defining layer;
wherein the via hole of the pixel defining layer has a rectangular cross section in a direction parallel to the substrate, and an inverted trapezoid cross section perpendicular to the direction of the substrate; wherein, the inverted trapezoid is an isosceles trapezoid, and an angle between the waist of the inverted trapezoid and the vertical direction is greater than or equal to 5°.

2. The OLED display panel according to claim 1, wherein the anode of the light emitting unit is a laminated structure of a first transparent conductive layer/a second reflective metal layer/a second transparent conductive layer.

3. The OLED display panel according to claim 2, wherein a material of the first reflective metal layer and the second reflective metal layer is silver.

4. An organic light emitting diode (OLED) display panel, comprising:
a substrate;
a thin film transistor (TFT) layer on the substrate;
a pixel defining layer above the TFT layer, the pixel defining layer having a via hole;
a light emitting unit located in the via hole of the pixel defining layer, the light emitting unit comprises an anode located at a bottom of the via hole, an organic light emitting material above the anode, a cathode located above the organic light emitting material, and a first reflective metal layer between the organic light emitting material and the pixel defining layer.

5. The OLED display panel according to claim 4, wherein the anode of the light emitting unit is a laminated structure of a first transparent conductive layer/a second reflective metal layer/a second transparent conductive layer.

6. The OLED display panel according to claim 5, wherein a material of the first reflective metal layer and the second reflective metal layer is silver.

7. The OLED display panel according to claim 4, wherein the via hole of the pixel defining layer has a rectangular cross section in a direction parallel to the substrate, and an inverted trapezoid cross section perpendicular to the direction of the substrate; wherein, the inverted trapezoid is an isosceles trapezoid, and an angle between the waist of the inverted trapezoid and the vertical direction is greater than or equal to 5°.

8. A method of manufacturing an organic light emitting diode (OLED) display panel comprising the steps of:
providing a substrate;
forming a thin film transistor (TFT) layer on the substrate;
forming a patterned pixel defining layer over the TFT layer, the pixel defining layer having a via hole;
forming a light emitting unit in the via hole of the pixel defining layer; wherein
the light emitting unit comprises an anode located at a bottom of the via hole, an organic light emitting material above the anode, a cathode located above the organic light emitting material, and a first reflective metal layer between the organic light emitting material and the pixel defining layer.

9. The method of manufacturing an OLED display panel according to claim 8, wherein a method of forming a patterned pixel definition layer over the TFT layer comprises the steps of:
depositing an insulating material layer over the thin film transistor;
coating a photoresist over the insulating material layer;
developing the photoresist with a set mask to remove the photoresist over a region where the via hole is to be formed;
removing the insulating material layer not covered by the photoresist by etching, forming a via hole penetrating the insulating material layer, exposing the thin film transistor layer underlying the insulating material layer.

10. The method of manufacturing an OLED display panel according to claim 9, wherein a method of etching the insulating material layer is dry etching, comprising ion milling etching, plasma etching, and reactive ion etching.

11. The method of manufacturing an OLED display panel according to claim 8, wherein a method of forming a light emitting unit in the via hole of the pixel defining layer comprises the steps of:
evaporating the anode at the bottom of the via hole;
forming the first reflective metal layer on a sidewall of the via hole defined by the pixel defining layer, the first reflective metal layer is disposed above the anode;
forming an organic light emitting material above the anode, a sidewall of the organic light emitting material is disposed adjacent to the first reflective metal layer;
forming the cathode over the organic light emitting material.

12. The method of manufacturing an OLED display panel according to claim 11, wherein a method of evaporating the anode at the bottom of the via hole comprises the steps of:
forming a photoresist covering a top and a sidewall of the pixel defining layer;
forming a stacked structure covering the photoresist and the via hole, the stacked structure comprises a first transparent conductive layer at a bottom of the pixel defining layer, a second reflective metal layer disposed above the first transparent conductive layer, and a second transparent conductive layer above the second reflective metal layer;
removing the photoresist, and so that the stacked structure over the photoresist is removed to form the anode at the bottom of the via hole.

13. The method of manufacturing an OLED display panel according to claim 11, wherein a method of forming a first reflective metal layer on a sidewall of the via hole of the pixel defining layer comprises the steps of:
forming a metal layer covering the anode, the top, and sidewall of the pixel defining layer;
forming a photoresist covering the metal layer, and patterning the photoresist to cover only a metal layer located on a sidewall of the pixel defining layer;
removing a metal layer not covered by the photoresist by photolithography, and then removing the photoresist.
